(19) United States
(12) Patent Application Publication
(10) Pub. No.: US 2022/0268964 A1
(43) Pub. Date: Aug. 25, 2022

(54) Method Of Predicting Amount Of Precipitation Based On Deep Learning

(71) Applicant: SI Analytics Co., Ltd., Daejeon (KR)

(72) Inventor: Yeji CHOI, Daejeon (KR)

(73) Assignee: SI Analytics Co., Ltd., Daejeon (KR)

(21) Appl. No.: 17/672,431

(22) Filed: Feb. 15, 2022

(30) Foreign Application Priority Data
Feb. 19, 2021 (KR) 10-2021-0022765

(51) Int. Cl. G01W 1/10; G06N 3/08; G01W 1/14

(52) U.S. Cl. CPC G01W 1/10; G06N 3/08; G01W 1/14

(57) ABSTRACT

According to an exemplary embodiment of the present disclosure, a method of predicting the amount of precipitation based on deep learning performed by a computing device is disclosed. The method may include: receiving meteorological data measured in a weather observation system; and predicting the amount of precipitation of a region of interest based on the meteorological data by using a deep learning model. In this case, the deep learning model may be pre-trained based on a combination of a first loss function for an error calculation between a prediction value and Ground Truth (GT), and a second loss function for an error calculation different from the first loss function.

### CROSS-REFERENCE TO RELATED APPLICATIONS

This application claims priority to and the benefit of Korean Patent Application No. 10-2021-0022765 filed in the Korean Intellectual Property Office on Feb. 19, 2021, the entire contents of which are incorporated herein by reference.

### TECHNICAL FIELD

The present disclosure relates to a method of predicting the amount of precipitation, and more particularly, to a deep learning technology for predicting the amount of precipitation based on weather observation data.

### BACKGROUND ART

The amount of precipitation has a significant impact on our daily lives, and heavy rains can cause serious disasters including flash floods and landslides, putting our health and infrastructure at risk. So far, physically-based Numerical Weather Prediction (NWP) models have been mainly used for weather forecasting. Although the prediction techniques of NWP models for precipitation have been greatly improved, accurate prediction of the amount of precipitation and the location of precipitation remains an important task due to the various microphysical properties of clouds and precipitation processes depending on environmental settings. For example, in the Weather Research and Forecasting (WRF) model that is one of the best-known NWP models, various microphysical parameterization methods are used to describe cloud and precipitation processes based on various statistical relationships.

Recently, deep learning technologies have shown the potential to predict weather events from weather and climate data itself with a non-physical approach. There have been many studies for predicting the amount of precipitation by using the deep learning technique. Most of the existing studies have used observation data using radar and satellites. The observation data using radar and satellites provides valuable information regarding patterns in precipitation regions. However, the pattern does not provide sufficient information related to atmospheric conditions to explain precipitation generation, duration, or disappearance.

Korean Patent Application Laid-Open No. 10-2009-0131564 (Dec. 29, 2009) discloses a system and a method of analyzing weather satellite data based on a web.

### SUMMARY OF THE INVENTION

The present disclosure has been conceived in response to the foregoing background art, and has been made in an effect to provide a method of quantitatively predicting the amount of precipitation per hour using meteorological data measured through a weather observation system based on deep learning.

In order to solve the foregoing object, an exemplary embodiment of the present disclosure discloses a method of predicting the amount of precipitation based on deep learning performed by a computing device. The method may include: receiving meteorological data measured in a weather observation system; and predicting the amount of precipitation of a region of interest based on the meteorological data by using a deep learning model. In this case, the deep learning model may be pre-trained based on a combination of a first loss function for an error calculation between a prediction value and Ground Truth (GT), and a second loss function for an error calculation different from the first loss function.

In an alternative exemplary embodiment, the meteorological data may include: a first input characteristic including an atmospheric state variable based on meteorological information measured in the weather observation system; and a second input characteristic including a geophysical variable based on the meteorological information measured in the weather observation system.

In the alternative exemplary embodiment, the atmospheric state variable may include at least one of temperature, wind direction, wind speed, the amount of precipitation, earth surface pressure, sea level pressure, and humidity at a point where the meteorological information is measured.

In the alternative exemplary embodiment, the geophysical variable may include at least one of a longitude, latitude, an altitude of the point at which the meteorological information is measured, and identification information of the weather observation system.

In the alternative exemplary embodiment, the first loss function may include a loss function for calculating a Mean Squared Error (MSE). Further, the second loss function may include a loss function for calculating a Mean Absolute Error (MAE).

In the alternative exemplary embodiment, the combination of the first loss function and the second loss function may be expressed by a sum of the first loss function and the second loss function to which a predetermined weight is applied.

In the alternative exemplary embodiment, the deep learning model may include at least one neural network which receives the meteorological data and outputs a rainfall rate of the region of interest at a time point at which a predetermined lead time has elapsed based on an observation time point of the meteorological data.

In the alternative exemplary embodiment, when the neural networks are two or more, each of the two or more neural networks may receive meteorological data observed at a different time point and output a rainfall rate of the region of interest.

In order to solve the foregoing object, another exemplary embodiment of the present disclosure discloses a computer program stored in a computer readable storage medium. When the computer program is executed by one or more processors, the computer program may perform following operations for predicting the amount of precipitation based on deep learning, and the operations may include: receiving meteorological data measured by a weather observation system; and predicting the amount of precipitation of a region of interest based on the meteorological data by using a deep learning model. In this case, the deep learning model may be pre-trained based on a combination of a first loss function for an error calculation between a prediction value and Ground Truth (GT), and a second loss function for an error calculation different from the first loss function.

In order to solve the foregoing object, another exemplary embodiment of the present disclosure discloses a computing device for predicting the amount of precipitation based on deep learning. The device may include: a processor including at least one core; a memory including program codes executable in the processor; and a network unit configured to receive meteorological data measured in a weather observation system, in which the processor may predict the amount of precipitation of a region of interest based on the meteorological data by using a deep learning model. In this case, the deep learning model may be pre-trained based on a combination of a first loss function for an error calculation between a prediction value and Ground Truth (GT), and a second loss function for an error calculation different from the first loss function.

The present disclosure may provide a method of quantitatively predicting the amount of precipitation per time by using meteorological data measured through a weather observation system based on deep learning.

### BRIEF DESCRIPTION OF THE DRAWINGS

FIG. 1 is a block diagram of a computing device for predicting the amount of precipitation based on deep learning according to an exemplary embodiment of the present disclosure.

FIG. 2 is a schematic diagram illustrating a network function according to the exemplary embodiment of the present disclosure.

FIG. 3 is a block diagram illustrating a process of predicting the amount of precipitation of the computing device according to the exemplary embodiment of the present disclosure.

FIG. 4 is a block diagram illustrating an architecture of a deep learning model according to the exemplary embodiment of the present disclosure.

FIG. 5 is a graph illustrating a verification result of the deep learning model according to the exemplary embodiment of the present disclosure.

FIG. 6 is a conceptual diagram illustrating a verification result of the deep learning model according to the exemplary embodiment of the present disclosure.

FIG. 7 is a flowchart illustrating a method of predicting the amount of precipitation based on deep learning according to an exemplary embodiment of the present disclosure.

FIG. 8 is a schematic diagram illustrating a computing environment according to an exemplary embodiment of the present disclosure.

### DETAILED DESCRIPTION

Various exemplary embodiments are described with reference to the drawings. In the present specification, various descriptions are presented for understanding the present disclosure. However, it is obvious that the exemplary embodiments may be carried out even without a particular description.

Terms, “component”, “module”, “system”, and the like used in the present specification indicate a computer-related entity, hardware, firmware, software, a combination of software and hardware, or execution of software. For example, a component may be a procedure executed in a processor, a processor, an object, an execution thread, a program, and/or a computer, but is not limited thereto. For example, both an application executed in a computing device and a computing device may be components. One or more components may reside within a processor and/or an execution thread. One component may be localized within one computer. One component may be distributed between two or more computers. Further, the components may be executed by various computer readable media having various data structures stored therein. For example, components may communicate through local and/or remote processing according to a signal (for example, data transmitted to another system through a network, such as the Internet, through data and/or a signal from one component interacting with another component in a local system and a distributed system) having one or more data packets.

A term “or” intends to mean comprehensive “or” not exclusive “or”. That is, unless otherwise specified or when it is unclear in context, “X uses A or B” intends to mean one of the natural comprehensive substitutions. That is, when X uses A, X uses B, or X uses both A and B, “X uses A or B” may be applied to any one among the cases. Further, a term “and/or” used in the present specification shall be understood to designate and include all of the possible combinations of one or more items among the listed relevant items.

It should be understood that a term “include” and/or “including” means that a corresponding characteristic and/or a constituent element exists. Further, a term “include” and/or “including” means that a corresponding characteristic and/or a constituent element exists, but it shall be understood that the existence or an addition of one or more other characteristics, constituent elements, and/or a group thereof is not excluded. Unless otherwise specified or when it is unclear in context that a single form is indicated, the singular shall be construed to generally mean “one or more” in the present specification and the claims.

The term “at least one of A and B” should be interpreted to mean “the case including only A”, “the case including only B”, and “the case where A and B are combined”.

Those skilled in the art shall recognize that the various illustrative logical blocks, configurations, modules, circuits, means, logic, and algorithm operations described in relation to the exemplary embodiments additionally disclosed herein may be implemented by electronic hardware, computer software, or in a combination of electronic hardware and computer software. In order to clearly exemplify interchangeability of hardware and software, the various illustrative components, blocks, configurations, means, logic, modules, circuits, and operations have been generally described above in the functional aspects thereof. Whether the functionality is implemented as hardware or software depends on a specific application or design restraints given to the general system. Those skilled in the art may implement the functionality described by various methods for each of the specific applications. However, it shall not be construed that the determinations of the implementation deviate from the range of the contents of the present disclosure.

The description about the presented exemplary embodiments is provided so as for those skilled in the art to use or carry out the present disclosure. Various modifications of the exemplary embodiments will be apparent to those skilled in the art. General principles defined herein may be applied to other exemplary embodiments without departing from the scope of the present disclosure. Therefore, the present disclosure is not limited to the exemplary embodiments presented herein. The present disclosure shall be interpreted within the broadest meaning range consistent to the principles and new characteristics presented herein.

In the present disclosure, a network function, an artificial neural network, and a neural network may be interchangeably used.

In the meantime, the “weather observation system” used in the detailed description and the claims of the present disclosure may be understood as a system for automatically performing observation for variables providing environmental information related to meteorological phenomenon. The weather observation system may include an observatory which automatically measures meteorological elements within a predetermined space at a predetermined time interval by using characteristics of various observing devices (for example, thermometers, hygrometers, and rain gauges). In this case, the weather observation system may refer to single weather observatory installed at a specific point on the ground, and may refer to a set (that is, a network) of various weather observatories. For example, the weather observation system may include an automated surface observing system (ASOS) and an automated weather stations (AWS). However, the weather observation system is not limited to the foregoing example, and may be understood that various devices and systems for performing weather observation based on the ground are included.

The term “meteorological data” used throughout the detailed description and claims of the present disclosure may be understood as observation data measured, stored and managed through the aforementioned weather observation system. For example, the meteorological data may include information on meteorological elements, such as temperature, wind direction, wind speed, the amount of precipitation, pressure, and humidity, measured through various observation devices included in the weather observation system. In addition, the meteorological data may include geographic information of the point at which the meteorological elements were measured. Information included in the meteorological data is not limited to the above-described examples, and may be variously configured within a range that can be understood by those skilled in the art.

The term “precipitation” used throughout the description and claims of this disclosure may be understood as a meteorological term meaning anything that water vapor condenses and falls on the ground during the Earth's water cycle. For example, In addition to rain and snow, so-called sleet, and dew can also be included in precipitation in addition to hail.

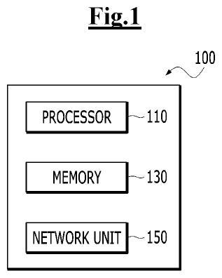

FIG. 1 is a block diagram of a computing device for predicting the amount of precipitation based on deep learning according to an exemplary embodiment of the present disclosure.

The configuration of a computing device 100 illustrated in FIG. 1 is merely a simplified example. In the exemplary embodiment of the present disclosure, the computing device 100 may include other configurations for performing a computing environment of the computing device 100, and only some of the disclosed configurations may also configure the computing device 100.

The computing device 100 may include a processor 110, a memory 130, and a network unit 150.

The processor 110 may be formed of one or more cores, and may include a processor, such as a central processing unit (CPU), a general purpose graphics processing unit (GPGPU), and a tensor processing unit (TPU) of the computing device, for performing a data analysis and deep learning. The processor 110 may read a computer program stored in the memory 130 and process data for machine learning according to an exemplary embodiment of the present disclosure. According to the exemplary embodiment of the present disclosure, the processor 110 may perform calculation for training a neural network. The processor 110 may perform a calculation, such as processing of input data for training in Deep Learning (DL), extraction of a feature from input data, an error calculation, and updating of a weight of the neural network by using backpropagation, for training the neural network. At least one of the CPU, GPGPU, and TPU of the processor 110 may process training of a network function. For example, the CPU and the GPGPU may process training of the network function and data classification by using a network function together. Further, in the exemplary embodiment of the present disclosure, the training of the network function and the data classification by using a network function may be processed by using the processors of the plurality of computing devices together. Further, the computer program executed in the computing device according to the exemplary embodiment of the present disclosure may be a CPU, GPGPU, or TPU executable program.

According to the exemplary embodiment of the present disclosure, the processor 110 may train a deep learning model based on meteorological data generated through a weather observation system. The processor 110 may train the deep learning model so as to predict the amount of precipitation of a region of interest based on the meteorological data. The processor 110 may train the deep learning model so as to predict the amount of precipitation at a future time point based on an observation time point of the meteorological data. For example, the processor 110 may use meteorological data generated by the ASOS and the AWS as training data of the deep learning model. The meteorological data is a set of time-series data and may be distinguished in the unit of time. The processor 110 may train the deep learning model by using the meteorological data as the training data, and a rainfall rate at the time point when a predetermined lead time has elapsed based on the observation time point of the meteorological data as a label.

The processor 110 may combine a plurality of loss functions for calculating different errors and use the combined loss function for training the deep learning model. The processor 110 use a combination of a first loss function for an error calculation between a prediction value and Ground Truth (GT) and a second loss function for an error calculation that is different from the first loss function for training the deep learning model. For example, the first loss function may include a loss function for calculating a Mean Squared Error (MSE). The second loss function may include a loss function for calculating a Mean Absolute Error (MAE). The processor 110 may train the deep learning model by combining two different loss functions as in the above example. In this case, the combination of the first loss function and the second loss function may be expressed as a sum of the first loss function and the second loss function to which a predetermined weight is applied. For example, in consideration of the fact that the MSE loss of the first loss function is larger than the MAE loss of the second loss function, in order to adjust a relative weight of the two loss functions, the loss function expressed with the sum of the first loss function and the second loss function in which a specific weight is multiplied may be used for training the deep learning model. As described above, when the combination of the loss functions performing the different error calculations is used for the training, the accuracy of the prediction of the amount of precipitation of the deep learning model may be improved compared to the case where a single loss function is used.

The processor 110 may predict the amount of precipitation of a region of interest by using the deep learning model pre-trained as described above based on meteorological data transmitted from the weather observation system. The processor 110 may predict the amount of precipitation of the region of interest at a future time point based on the observation time point of the meteorological data by inputting the meteorological data to the pre-trained deep learning model. For example, the processor 110 may collect meteorological data from the ASOS and the AWS and input the collected meteorological data to the deep learning model. In this case, the meteorological data may be collected from the ASOS and the AWS located in the region of interest or near the region of interest. The processor 110 may calculate a rainfall rate per time of the region of interest by inputting the meteorological data to the pre-trained deep learning model. The processor 110 may obtain a rainfall rate of a future time point when a predetermined time has elapsed based on the observation time point or time period of the meteorological data by using the deep learning model. A prediction value of the rainfall rate of the region of interest generated through the deep learning model according to the exemplary embodiment of the present disclosure may be used as a quantitative index that accurately represents a precipitation position and the amount of precipitation.

The processor 110 may visualize information about the amount of precipitation predicted through the pre-trained deep learning model. For example, the processor 110 may generate a precipitation map capable of showing a rainfall rate at a specific future time point for each region of interest. The processor 110 may generate a precipitation map having a different contrast or color according to the magnitude of the predicted rainfall rate, and may generate a user interface including the precipitation map. The processor 110 may also generate a table representing location information and a rainfall rate prediction value of the region of interest, as well as the precipitation map. That is, the processor 110 may visualize the information about the amount of precipitation predicted through the deep learning model in various formats, and generate a user interface based on the visualized format.

According to the exemplary embodiment of the present disclosure, the memory 130 may store a predetermined type of information generated or determined by the processor 110 and a predetermined type of information received by a network unit 150.

According to the exemplary embodiment of the present disclosure, the memory 130 may include at least one type of storage medium among a flash memory type, a hard disk type, a multimedia card micro type, a card type of memory (for example, an SD or XD memory), a Random Access Memory (RAM), a Static Random Access Memory (SRAM), a Read-Only Memory (ROM), an Electrically Erasable Programmable Read-Only Memory (EEPROM), a Programmable Read-Only Memory (PROM), a magnetic memory, a magnetic disk, and an optical disk. The computing device 100 may also be operated in relation to web storage performing a storage function of the memory 130 on the Internet. The description of the foregoing memory is merely illustrative, and the present disclosure is not limited thereto.

The network unit 150 according to the exemplary embodiment of the present disclosure may use a predetermined form of a publicly known wire/wireless communication system.

The network unit 150 may receive the meteorological data from the weather observation system. For example, the network unit 150 may receive meteorological data observed for each time from the ASOS and the AWS. The meteorological data may be the data for training of the deep learning model or the data for inference. The meteorological data may include information about the meteorological factors to which the characteristics of various observing devices are reflected, geographic information about an observation point or area, and the like.

The network unit 150 may transceive information processed by the processor 110, the user interface, and the like through communication with other terminals. For example, the network unit 150 may provide the user interface generated by the processor 110 to a client (for example, a user terminal). Further, the network unit 150 may receive the external input of the user applied to the client and transfer the received external input to the processor 110. In this case, the processor 110 may process the operations of output, correction, change, addition, and the like of the information provided through the user interface based on the external input of the user received from the network unit 150.

In the meantime, the computing device 100 according to the exemplary embodiment of the present disclosure is a computing system for transceiving information with the client through communication and may be a server. In this case, the client may be a predetermined type of terminal accessible to the server. For example, the computing device 100 that is the server may receive meteorological data from the weather observation system and predict the amount of precipitation, and provide a user terminal with a user interface based on a result of the prediction. In this case, the user terminal may output the user interface received from the computing device 100 that is the server, and input or process information through an interaction with a user.

In an additional exemplary embodiment, the computing device 100 may also include a predetermined form of terminal which receives data resources generated in a predetermined server and performs additional information processing.

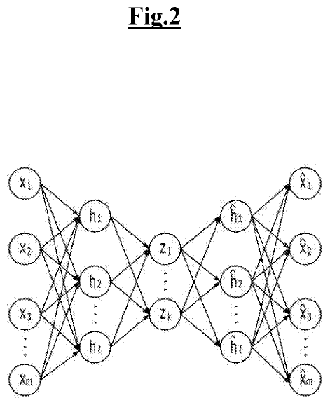

FIG. 2 is a schematic diagram illustrating a network function according to the exemplary embodiment of the present disclosure.

A deep learning model according to the exemplary embodiment of the present disclosure may include a neural network for predicting the amount of precipitation. Throughout the present specification, a nerve network, a network function, and the neural network may be used with the interchangeable meaning. The neural network may be formed of a set of interconnected calculation units which are generally referred to as “nodes”. The “nodes” may also be called “neurons”. The neural network consists of one or more nodes. The nodes (or neurons) configuring the neural network may be interconnected by one or more links.

In the neural network, one or more nodes connected through the links may relatively form a relationship of an input node and an output node. The concept of the input node is relative to the concept of the output node, and a predetermined node having an output node relationship with respect to one node may have an input node relationship in a relationship with another node, and a reverse relationship is also available. As described above, the relationship between the input node and the output node may be generated based on the link. One or more output nodes may be connected to one input node through a link, and a reverse case may also be valid.

In the relationship between an input node and an output node connected through one link, a value of the output node data may be determined based on data input to the input node. Herein, a link connecting the input node and the output node may have a weight. The weight is variable, and in order for the neural network to perform a desired function, the weight may be varied by a user or an algorithm. For example, when one or more input nodes are connected to one output node by links, respectively, a value of the output node may be determined based on values input to the input nodes connected to the output node and weights set in the link corresponding to each of the input nodes.

As described above, in the neural network, one or more nodes are connected with each other through one or more links to form a relationship of an input node and an output node in the neural network. A characteristic of the neural network may be determined according to the number of nodes and links in the neural network, a correlation between the nodes and the links, and a value of the weight assigned to each of the links. For example, when there are two neural networks in which the numbers of nodes and links are the same and the weight values between the links are different, the two neural networks may be recognized to be different from each other.

The neural network may consist of a set of one or more nodes. A subset of the nodes configuring the neural network may form a layer. Some of the nodes configuring the neural network may form one layer based on distances from an initial input node. For example, a set of nodes having a distance of n from an initial input node may form n layers. The distance from the initial input node may be defined by the minimum number of links, which need to be passed to reach a corresponding node from the initial input node. However, the definition of the layer is arbitrary for the description, and a degree of the layer in the neural network may be defined by a different method from the foregoing method. For example, the layers of the nodes may be defined by a distance from a final output node.

The initial input node may mean one or more nodes to which data is directly input without passing through a link in a relationship with other nodes among the nodes in the neural network. Otherwise, the initial input node may mean nodes which do not have other input nodes connected through the links in a relationship between the nodes based on the link in the neural network. Similarly, the final output node may mean one or more nodes that do not have an output node in a relationship with other nodes among the nodes in the neural network. Further, the hidden node may mean nodes configuring the neural network, not the initial input node and the final output node.

In the neural network according to the exemplary embodiment of the present disclosure, the number of nodes of the input layer may be the same as the number of nodes of the output layer, and the neural network may be in the form that the number of nodes decreases and then increases again from the input layer to the hidden layer. Further, in the neural network according to another exemplary embodiment of the present disclosure, the number of nodes of the input layer may be smaller than the number of nodes of the output layer, and the neural network may be in the form that the number of nodes decreases from the input layer to the hidden layer. Further, in the neural network according to another exemplary embodiment of the present disclosure, the number of nodes of the input layer may be larger than the number of nodes of the output layer, and the neural network may be in the form that the number of nodes increases from the input layer to the hidden layer. The neural network according to another exemplary embodiment of the present disclosure may be the neural network in the form in which the foregoing neural networks are combined.

A deep neural network (DNN) may mean the neural network including a plurality of hidden layers, in addition to an input layer and an output layer. When the DNN is used, it is possible to recognize a latent structure of data. That is, it is possible to recognize latent structures of photos, texts, videos, voice, and music (for example, what objects are in the photos, what the content and emotions of the texts are, and what the content and emotions of the voice are). The DNN may include a convolutional neural network (CNN), a recurrent neural network (RNN), an auto encoder, Generative Adversarial Networks (GAN), a restricted Boltzmann machine (RBM), a deep belief network (DBN), a Q network, a U network Siamese network, and the like. The foregoing description of the deep neural network is merely illustrative, and the present disclosure is not limited thereto.

In the exemplary embodiment of the present disclosure, the network function may include an auto encoder. The auto encoder may be one type of artificial neural network for outputting output data similar to input data. The auto encoder may include at least one hidden layer, and the odd-numbered hidden layers may be disposed between the input/output layers. The number of nodes of each layer may decrease from the number of nodes of the input layer to an intermediate layer called a bottleneck layer (encoding), and then be expanded symmetrically with the decrease from the bottleneck layer to the output layer (symmetric with the input layer). The auto encoder may perform a nonlinear dimension reduction. The number of input layers and the number of output layers may correspond to the dimensions after preprocessing of the input data. In the auto encoder structure, the number of nodes of the hidden layer included in the encoder decreases as a distance from the input layer increases. When the number of nodes of the bottleneck layer (the layer having the smallest number of nodes located between the encoder and the decoder) is too small, the sufficient amount of information may not be transmitted, so that the number of nodes of the bottleneck layer may be maintained in a specific number or more (for example, a half or more of the number of nodes of the input layer and the like).

The neural network may be trained by at least one scheme of supervised learning, unsupervised learning, semi-supervised learning, and reinforcement learning. The training of the neural network may be a process of applying knowledge for the neural network to perform a specific operation to the neural network.

The neural network may be trained in a direction of minimizing an error of an output. In the training of the neural network, training data is repeatedly input to the neural network and an error of an output of the neural network for the training data and a target is calculated, and the error of the neural network is back-propagated in a direction from an output layer to an input layer of the neural network in order to decrease the error, and a weight of each node of the neural network is updated. In the case of the supervised learning, training data labelled with a correct answer (that is, labelled training data) is used, in each training data, and in the case of the unsupervised learning, a correct answer may not be labelled to each training data. That is, for example, the training data in the supervised learning for data classification may be data, in which category is labelled to each of the training data. The labelled training data is input to the neural network and the output (category) of the neural network is compared with the label of the training data to calculate an error. For another example, in the case of the unsupervised learning related to the data classification, training data that is the input is compared with an output of the neural network, so that an error may be calculated. The calculated error is back-propagated in a reverse direction (that is, the direction from the output layer to the input layer) in the neural network, and a connection weight of each of the nodes of the layers of the neural network may be updated according to the backpropagation. A change amount of the updated connection weight of each node may be determined according to a learning rate. The calculation of the neural network for the input data and the backpropagation of the error may configure a learning epoch. The learning rate is differently applicable according to the number of times of repetition of the learning epoch of the neural network. For example, at the initial stage of the learning of the neural network, a high learning rate is used to make the neural network rapidly secure performance of a predetermined level and improve efficiency, and at the latter stage of the learning, a low learning rate is used to improve accuracy.

In the training of the neural network, the training data may be generally a subset of actual data (that is, data to be processed by using the trained neural network), and thus an error for the training data is decreased, but there may exist a learning epoch, in which an error for the actual data is increased. Overfitting is a phenomenon, in which the neural network excessively learns training data, so that an error for actual data is increased. For example, a phenomenon, in which the neural network learning a cat while seeing a yellow cat cannot recognize cats, other than a yellow cat, as cats, is a sort of overfitting. Overfitting may act as a reason of increasing an error of a machine learning algorithm. In order to prevent overfitting, various optimizing methods may be used. In order to prevent overfitting, a method of increasing training data, a regularization method, a dropout method of inactivating a part of nodes of the network during the learning process, a method using a bath normalization layer, and the like may be applied.

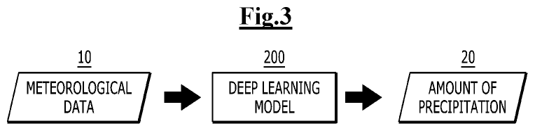

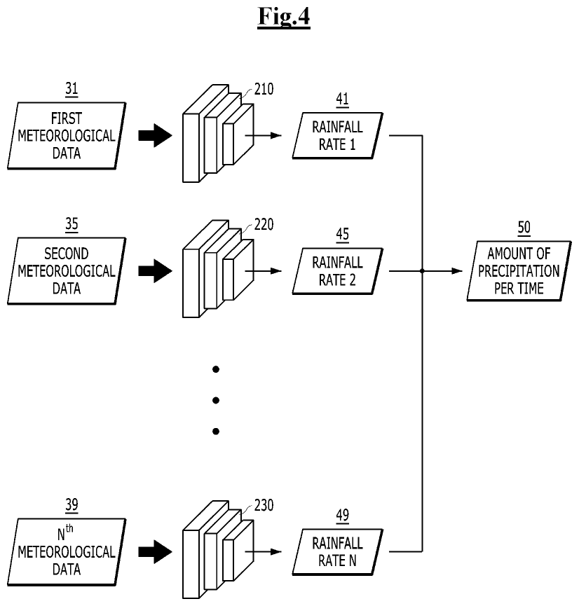

FIG. 3 is a block diagram illustrating a process of predicting the amount of precipitation of the computing device according to the exemplary embodiment of the present disclosure. FIG. 4 is a block diagram illustrating an architecture of a deep learning model according to an exemplary embodiment of the present disclosure.

Referring to FIG. 3, the computing device 100 according to the exemplary embodiment of the present disclosure may derive a short-term prediction result 20 of the amount of precipitation for a specific region based on metrological data 10 measured by the weather observation system by using a pre-trained deep learning model 200. The computing device 100 may perform scale correction on variables which are to be used as input characteristics of the deep learning model 200 by considering the fact that the numerical value range of meteorological variables included in the meteorological data 10 is various. The computing device 100 may input the meteorological data 10 in which the numerical values of the meteorological variables are scale-corrected to the deep learning model 200 and acquire a quantified prediction value 20 related to the amount of precipitation at a future time point based on the observation time point of the meteorological data 10. The prediction value 20 of the amount of precipitation may include location information of the specific region, and information about the expected rainfall rate per time of the specific region.

The meteorological data 10 collected from the weather observation system may include meteorological information representing meteorological variables that affect the prediction of the occurrence and the degree of precipitation. In this case, the meteorological information may include geological information about the point or the region in which the meteorological data 10 has been measured. At least a part of the meteorological information included in the meteorological data 10 may be used as the input characteristic of the deep learning model 200. For example, the input characteristic of the deep learning model 200 may include a first input characteristic including an atmospheric state variable based on the meteorological information of the meteorological data 10 and a second input characteristic including a geophysical variable based on the meteorological information of the meteorological data 10. The atmospheric state variable included in the first input characteristic may include at least one of temperature, wind direction, wind speed, the amount of precipitation, earth surface pressure, sea level pressure, and humidity at the point where the meteorological information is measured. Further, the geophysical variable included in the second input characteristic may include at least one of a longitude, a latitude, an altitude of the point at which the meteorological information is measured, and identification information of the weather observation system. A total of 11 types of atmospheric state variables and geophysical variables such as the above examples are variables that best represent the characteristics of meteorological factors required for quantitative prediction of the amount of precipitation in the specific region and geographic characteristics. Therefore, when the first input characteristic and the second input characteristic are used, it is possible to effectively improve accuracy of the prediction of the amount of precipitation through the deep learning model 200.

The deep learning model 200 according to the exemplary embodiment of the present disclosure may include at least one neural network which receives the meteorological data 10 and outputs a rainfall rate of a region of interest at a point at which a predetermined lead time has elapsed based on an observation time point of the meteorological data 10. In this case, the predetermined lead time may be in units of hours, such as 1 hour and 2 hours, as well as in minutes, such as 30 minutes. For example, the deep learning model 200 may include a neural network consisting of a plurality of fully-connected layers. An input layer of the neural network may use the foregoing input characteristic of the meteorological data 10 per time. When the neural network includes five fully-connected layers, a dimension of a hidden layer of the neural network may be configured as 64, 32, 16, 8, and 4. An activation function used for the training of the neural network may be Rectified Linear Unit (ReLU) function. An optimizer used for training the neural network may be Adaptive moment estimation (Adam). The detailed description related to the structure of the neural network and the function is merely an example, and the structure of the neural network and the function are not limited thereto and may be changed within a range that can be understood by those skilled in the art.

When the neural networks included in the deep learning model 200 are two or more, each of the two or more neural networks may receive meteorological data observed at different time points and output a rainfall rate of the region of interest. For example, referring to FIG. 4, the deep learning model 200 may include a plurality of neural networks 210, 220, and 230 calculating the rainfall rate at the time point at which the predetermined lead time has elapsed based on the observation time point of the meteorological data. A first neural network 210 may receive first meteorological data 31 observed at time point A and output a rainfall rate 1 41 that is an quantitative index representing the amount of precipitation at time point A+1 at which the lead time has elapsed from time point A. A second neural network 220 may receive second meteorological data 35 observed at time point B and output a rainfall rate 2 45 that is an quantitative index representing the amount of precipitation at time point B+1 at which the lead time has elapsed from time point B. An N^{th} neural network 230 (N is a natural number) may receive N^{th} meteorological data 39 observed at time point C and output a rainfall rate N 49 that is an quantitative index representing the amount of precipitation at time point C+1 at which the lead time has elapsed from time point C. In this case, time point A, time point B, and time point C may be different from one another. When the rainfall rates 41, 45, and 49 are output from the plurality of neural networks 210, 220, and 230 based on the meteorological data 31, 35, and 39 at the different time points, respectively, the deep learning model 200 may generate the amount of precipitation 50 per time based on the rainfall rates 41, 45, and 49. By processing the meteorological data in parallel according to the observation time point of the plurality of neural networks as described above, it is possible to rapidly and accurately obtain precipitation amount prediction information desired by the user per time. In the meantime, the plurality of neural networks may also be configured to have the same structure, and may also be configured to have different structures.

In order to validate the deep learning model according to the exemplary embodiment of the present disclosure, the deep learning model and the data are established and the deep learning model is evaluated as described below.

As the data for training, validating, and testing the deep learning model, meteorological data measured by the ASOS and the AWS with a spatial resolution of about 13 km on the Korean Peninsula and collected for about three years were used. Among the meteorological data, six time-specific data recorded during the previous six hours were used as input data, and a rainfall rate per hour of the lead time of 1 hour to 6 hours was used as a label. The deep learning model was configured to include six neural networks which receive the six time-specific data individually. In addition, as the loss function used for training the deep learning model, the loss function composed of the sum of the MSE loss function and the MAE loss function in which a constant weight is multiplied was used.

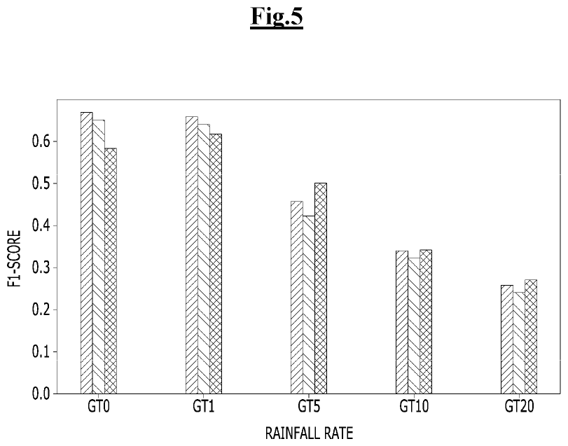

FIG. 5 represents a result of the test of the deep learning models divided according to the loss function. Of the three bar graphs for each rainfall rate, the left bar graph shows the test results of the deep learning model trained using the loss function in which the MSE loss function is combined with the MAE loss function. Of the three bar graphs for each rainfall rate, the middle bar graph shows the test results of the deep learning model trained using the single MAE loss function. Of the three bar graphs for each rainfall rate, the right bar graph shows the test results of the deep learning model trained using the single MSE loss function. Referring to FIG. 5, it can be seen that when the single MSE loss function is used, it shows a relatively good F1 score based on a precipitation rainfall of 5 mm/h (GT5) or higher. On the other hand, it can be seen that when the single MAE loss function is used, it shows a relatively good F1 score based on a precipitation rainfall of less than 5 mm/h (GT5). It can be seen that when the loss function in which the MSE loss function and the MAE loss function are combined is used according to the exemplary embodiment of the present disclosure, it shows a relatively good F1 score for all rainfall rates compared to the case where the single loss function is used. That is, referring to FIG. 5, it can be confirmed that compared to the use of the single loss function, using the combined loss function according to the exemplary embodiment of the present disclosure guarantees better rainfall rate prediction performance of the deep learning model.

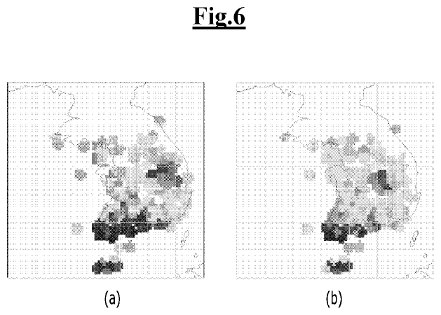

FIG. 6 represents a precipitation map configured based on an actual observation result and a prediction result. (a) of FIG. 6 is a precipitation map generated based on an actual observation result, and (b) of FIG. 6 is a precipitation map generated based on a result predicted through the deep learning model according to the exemplary embodiment of the present disclosure. The contrast displayed on the precipitation map depends on the magnitude of the rainfall rate. In the precipitation map, the contrast of each region becomes darker as the magnitude of the rainfall rate increases. Comparing (a) and (b) of FIG. 6, it can be seen that the distributions of the rainfall rates for each region between the actual observation result and the prediction result are considerably consistent. That is, referring to FIG. 6, it can be seen that when the deep learning model according to the exemplary embodiment of the present disclosure is used, it is possible to predict a rainfall rate considerably close (that is, with high accuracy) to the actual observation result.

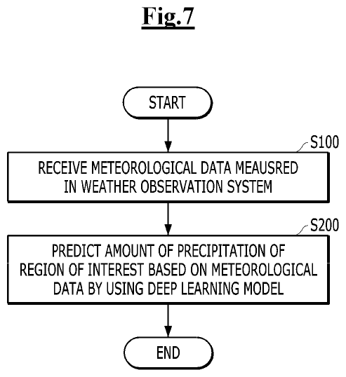

FIG. 7 is a flowchart illustrating a method of predicting the amount of precipitation based on deep learning according to an exemplary embodiment of the present disclosure.

Referring to FIG. 7, in operation S100, the computing device 100 according to an exemplary embodiment of the present disclosure may receive meteorological data measured by a weather observation system. The weather observation system may include an observatory that is located on the earth surface to automatically observe a meteorological phenomenon according to a predetermine period, and generates meteorological data according to an observation result. The computing device 100 may collect meteorological data through communication with the observatory within a region including a region of interest for which meteorological prediction is desired. The meteorological data may include atmospheric state variables related to meteorological factors affecting the prediction of the amount of precipitation, geophysical variables representing geographic information about an observation point or region, and the like. When the earth surface observation data is used as described above, it is relatively easy to obtain data compared to radar and satellites, so that precipitation prediction may be performed with lower computing and operating costs. Further, when the earth surface observation data is used, it is possible to accurately predict not only a precipitation pattern but also quantitative indexes of precipitation (for example, the amount of precipitation and the precipitation location).

In operation S200, the computing device 100 may perform preprocessing on numerical values for the variables included in the meteorological data collected in operation S100. In consideration of the fact that the ranges of the numerical values represented by the variables are different, the computing device 100 may perform a correction that matches scales of the variables included in the meteorological data. When the scale correction is completed, the computing device 100 may predict the amount of precipitation of the region of interest based on the pre-processed meteorological data by using a pre-trained deep learning model. In particular, the deep learning model may predict the amount of precipitation at a future time point for the region of interest based on input characteristics that are based on the atmospheric state variables, geophysical variables, and the like included in the meteorological data. In this case, the future time point may be understood as a time point when a predetermined lead time has elapsed based on the observation time point of the meteorological data.

In operation S200, the computing device 100 may visualize information about the amount of precipitation predicted through the deep learning model and generate a user interface. For example, the computing device 100 may generate a precipitation map in which the region of interest and the distribution of the rainfall rate of the region of interest are recognizable at a glance, or a table in which location information and a prediction value of the rainfall rate of the region of interest are digitized and displayed.

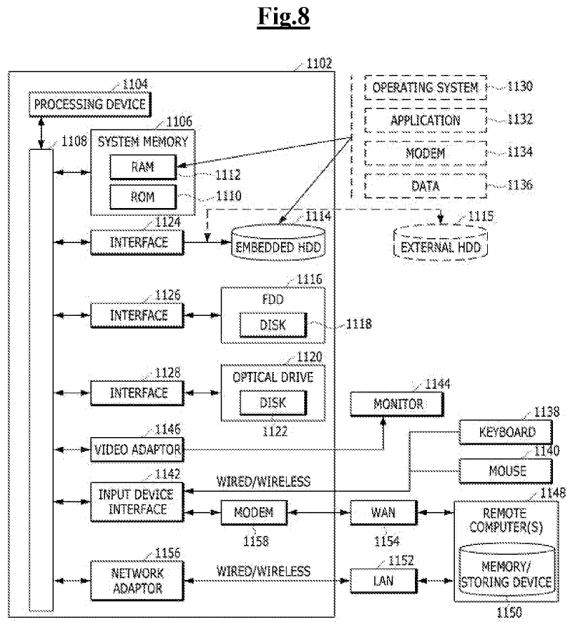

FIG. 8 is a simple and general schematic diagram for an example of a computing environment in which exemplary embodiments of the present disclosure are implementable.

The present disclosure has been described as being generally implementable by the computing device, but those skilled in the art will appreciate well that the present disclosure is combined with computer executable commands and/or other program modules executable in one or more computers and/or be implemented by a combination of hardware and software.

In general, a program module includes a routine, a program, a component, a data structure, and the like performing a specific task or implementing a specific abstract data form. Further, those skilled in the art will appreciate well that the method of the present disclosure may be carried out by a personal computer, a hand-held computing device, a microprocessor-based or programmable home appliance (each of which may be connected with one or more relevant devices and be operated), and other computer system configurations, as well as a single-processor or multiprocessor computer system, a mini computer, and a main frame computer.

The exemplary embodiments of the present disclosure may be carried out in a distribution computing environment, in which certain tasks are performed by remote processing devices connected through a communication network. In the distribution computing environment, a program module may be located in both a local memory storage device and a remote memory storage device.

The computer generally includes various computer readable media. The computer accessible medium may be any type of computer readable medium, and the computer readable medium includes volatile and non-volatile media, transitory and non-transitory media, and portable and non-portable media. As a non-limited example, the computer readable medium may include a computer readable storage medium and a computer readable transmission medium. The computer readable storage medium includes volatile and non-volatile media, transitory and non-transitory media, and portable and non-portable media constructed by a predetermined method or technology, which stores information, such as a computer readable command, a data structure, a program module, or other data. The computer readable storage medium includes a Random Access Memory (RAM), a Read Only Memory (ROM), an Electrically Erasable and Programmable ROM (EEPROM), a flash memory, or other memory technologies, a Compact Disc (CD)-ROM, a Digital Video Disk (DVD), or other optical disk storage devices, a magnetic cassette, a magnetic tape, a magnetic disk storage device, or other magnetic storage device, or other predetermined media, which are accessible by a computer and are used for storing desired information, but is not limited thereto.

The computer readable transport medium generally implements a computer readable command, a data structure, a program module, or other data in a modulated data signal, such as a carrier wave or other transport mechanisms, and includes all of the information transport media. The modulated data signal means a signal, of which one or more of the characteristics are set or changed so as to encode information within the signal. As a non-limited example, the computer readable transport medium includes a wired medium, such as a wired network or a direct-wired connection, and a wireless medium, such as sound, Radio Frequency (RF), infrared rays, and other wireless media. A combination of the predetermined media among the foregoing media is also included in a range of the computer readable transport medium.

An illustrative environment 1100 including a computer 1102 and implementing several aspects of the present disclosure is illustrated, and the computer 1102 includes a processing device 1104, a system memory 1106, and a system bus 1108. The system bus 1108 connects system components including the system memory 1106 (not limited) to the processing device 1104. The processing device 1104 may be a predetermined processor among various commonly used processors. A dual processor and other multi-processor architectures may also be used as the processing device 1104.

The system bus 1108 may be a predetermined one among several types of bus structure, which may be additionally connectable to a local bus using a predetermined one among a memory bus, a peripheral device bus, and various common bus architectures. The system memory 1106 includes a ROM 1110, and a RAM 1112. A basic input/output system (BIOS) is stored in a non-volatile memory 1110, such as a ROM, an EPROM, and an EEPROM, and the BIOS includes a basic routing helping a transport of information among the constituent elements within the computer 1102 at a time, such as starting. The RAM 1112 may also include a high-rate RAM, such as a static RAM, for caching data.

The computer 1102 also includes an embedded hard disk drive (HDD) 1114 (for example, enhanced integrated drive electronics (EIDE) and serial advanced technology attachment (SATA))—the embedded HDD 1114 being configured for exterior mounted usage within a proper chassis (not illustrated)—a magnetic floppy disk drive (FDD) 1116 (for example, which is for reading data from a portable diskette 1118 or recording data in the portable diskette 1118), and an optical disk drive 1120 (for example, which is for reading a CD-ROM disk 1122, or reading data from other high-capacity optical media, such as a DVD, or recording data in the high-capacity optical media). A hard disk drive 1114, a magnetic disk drive 1116, and an optical disk drive 1120 may be connected to a system bus 1108 by a hard disk drive interface 1124, a magnetic disk drive interface 1126, and an optical drive interface 1128, respectively. An interface 1124 for implementing an exterior mounted drive includes, for example, at least one of or both a universal serial bus (USB) and the Institute of Electrical and Electronics Engineers (IEEE) 1394 interface technology.

The drives and the computer readable media associated with the drives provide non-volatile storage of data, data structures, computer executable commands, and the like. In the case of the computer 1102, the drive and the medium correspond to the storage of random data in an appropriate digital form. In the description of the computer readable media, the HDD, the portable magnetic disk, and the portable optical media, such as a CD, or a DVD, are mentioned, but those skilled in the art will well appreciate that other types of computer readable media, such as a zip drive, a magnetic cassette, a flash memory card, and a cartridge, may also be used in the illustrative operation environment, and the predetermined medium may include computer executable commands for performing the methods of the present disclosure.

A plurality of program modules including an operation system 1130, one or more application programs 1132, other program modules 1134, and program data 1136 may be stored in the drive and the RAM 1112. An entirety or a part of the operation system, the application, the module, and/or data may also be cached in the RAM 1112. It will be well appreciated that the present disclosure may be implemented by several commercially usable operation systems or a combination of operation systems.

A user may input a command and information to the computer 1102 through one or more wired/wireless input devices, for example, a keyboard 1138 and a pointing device, such as a mouse 1140. Other input devices (not illustrated) may be a microphone, an IR remote controller, a joystick, a game pad, a stylus pen, a touch screen, and the like. The foregoing and other input devices are frequently connected to the processing device 1104 through an input device interface 1142 connected to the system bus 1108, but may be connected by other interfaces, such as a parallel port, an IEEE 1394 serial port, a game port, a USB port, an IR interface, and other interfaces.

A monitor 1144 or other types of display devices are also connected to the system bus 1108 through an interface, such as a video adaptor 1146. In addition to the monitor 1144, the computer generally includes other peripheral output devices (not illustrated), such as a speaker and a printer.

The computer 1102 may be operated in a networked environment by using a logical connection to one or more remote computers, such as remote computer(s) 1148, through wired and/or wireless communication. The remote computer(s) 1148 may be a work station, a computing device computer, a router, a personal computer, a portable computer, a microprocessor-based entertainment device, a peer device, and other general network nodes, and generally includes some or an entirety of the constituent elements described for the computer 1102, but only a memory storage device 1150 is illustrated for simplicity. The illustrated logical connection includes a wired/wireless connection to a local area network (LAN) 1152 and/or a larger network, for example, a wide area network (WAN) 1154. The LAN and WAN networking environments are general in an office and a company, and make an enterprise-wide computer network, such as an Intranet, easy, and all of the LAN and WAN networking environments may be connected to a worldwide computer network, for example, the Internet.

When the computer 1102 is used in the LAN networking environment, the computer 1102 is connected to the local network 1152 through a wired and/or wireless communication network interface or an adaptor 1156. The adaptor 1156 may make wired or wireless communication to the LAN 1152 easy, and the LAN 1152 also includes a wireless access point installed therein for the communication with the wireless adaptor 1156. When the computer 1102 is used in the WAN networking environment, the computer 1102 may include a modem 1158, is connected to a communication computing device on a WAN 1154, or includes other means setting communication through the WAN 1154 via the Internet. The modem 1158, which may be an embedded or outer-mounted and wired or wireless device, is connected to the system bus 1108 through a serial port interface 1142. In the networked environment, the program modules described for the computer 1102 or some of the program modules may be stored in a remote memory/storage device 1150. The illustrated network connection is illustrative, and those skilled in the art will appreciate well that other means setting a communication link between the computers may be used.

The computer 1102 performs an operation of communicating with a predetermined wireless device or entity, for example, a printer, a scanner, a desktop and/or portable computer, a portable data assistant (PDA), a communication satellite, predetermined equipment or place related to a wirelessly detectable tag, and a telephone, which is disposed by wireless communication and is operated. The operation includes a wireless fidelity (Wi-Fi) and Bluetooth wireless technology at least. Accordingly, the communication may have a pre-defined structure, such as a network in the related art, or may be simply ad hoc communication between at least two devices.

The Wi-Fi enables a connection to the Internet and the like even without a wire. The Wi-Fi is a wireless technology, such as a cellular phone, which enables the device, for example, the computer, to transmit and receive data indoors and outdoors, that is, in any place within a communication range of a base station. A Wi-Fi network uses a wireless technology, which is called IEEE 802.11 (a, b, g, etc.) for providing a safe, reliable, and high-rate wireless connection. The Wi-Fi may be used for connecting the computer to the computer, the Internet, and the wired network (IEEE 802.3 or Ethernet is used). The Wi-Fi network may be operated at, for example, a data rate of 11 Mbps (802.11a) or 54 Mbps (802.11b) in an unauthorized 2.4 and 5 GHz wireless band, or may be operated in a product including both bands (dual bands).

In the meantime, according to an exemplary embodiment of the present disclosure, a computer readable medium storing a data structure is disclosed.

The data structure may refer to organization, management, and storage of data that enable efficient access and modification of data. The data structure may refer to organization of data for solving a specific problem (for example, data search, data storage, and data modification in the shortest time). The data structure may also be defined with a physical or logical relationship between the data elements designed to support a specific data processing function. A logical relationship between data elements may include a connection relationship between user defined data elements. A physical relationship between data elements may include an actual relationship between the data elements physically stored in a computer readable storage medium (for example, a permanent storage device). In particular, the data structure may include a set of data, a relationship between data, and a function or a command applicable to data. Through the effectively designed data structure, the computing device may perform a calculation while minimally using resources of the computing device. In particular, the computing device may improve efficiency of calculation, reading, insertion, deletion, comparison, exchange, and search through the effectively designed data structure.

The data structure may be divided into a linear data structure and a non-linear data structure according to the form of the data structure. The linear data structure may be the structure in which only one data is connected after one data. The linear data structure may include a list, a stack, a queue, and a deque. The list may mean a series of dataset in which order exists internally. The list may include a linked list. The linked list may have a data structure in which data is connected in a method in which each data has a pointer and is linked in a single line. In the linked list, the pointer may include information about the connection with the next or previous data. The linked list may be expressed as a single linked list, a double linked list, and a circular linked list according to the form. The stack may have a data listing structure with limited access to data. The stack may have a linear data structure that may process (for example, insert or delete) data only at one end of the data structure. The data stored in the stack may have a data structure (Last In First Out, LIFO) in which the later the data enters, the sooner the data comes out. The queue is a data listing structure with limited access to data, and may have a data structure (First In First Out, FIFO) in which the later the data is stored, the later the data comes out, unlike the stack. The deque may have a data structure that may process data at both ends of the data structure.

The non-linear data structure may be the structure in which the plurality of pieces of data is connected after one data. The non-linear data structure may include a graph data structure. The graph data structure may be defined with a vertex and an edge, and the edge may include a line connecting two different vertexes. The graph data structure may include a tree data structure. The tree data structure may be the data structure in which a path connecting two different vertexes among the plurality of vertexes included in the tree is one. That is, the tree data structure may be the data structure in which a loop is not formed in the graph data structure.

Throughout the present specification, a calculation model, a nerve network, the network function, and the neural network may be used with the same meaning. Hereinafter, the terms of the calculation model, the nerve network, the network function, and the neural network are unified and described with a neural network. The data structure may include a neural network. Further, the data structure including the neural network may be stored in a computer readable medium. The data structure including the neural network may also include data pre-processed by the processing by the neural network, data input to the neural network, a weight of the neural network, a hyper-parameter of the neural network, data obtained from the neural network, an active function associated with each node or layer of the neural network, and a loss function for training of the neural network. The data structure including the neural network may include predetermined configuration elements among the disclosed configurations. That is, the data structure including the neural network may also include all or a predetermined combination of preprocessed data for processing by the neural network, data input to the neural network, a weight of the neural network, a hyper-parameter of the neural network, data obtained from the neural network, an active function associated with each node or layer of the neural network, and a loss function for training of the neural network. In addition to the foregoing configurations, the data structure including the neural network may include predetermined other information determining a characteristic of the neural network. Further, the data structure may include all type of data used or generated in a computation process of the neural network, and is not limited to the foregoing matter. The computer readable medium may include a computer readable recording medium and/or a computer readable transmission medium. The neural network may be formed of a set of interconnected calculation units which are generally referred to as “nodes”. The “nodes” may also be called “neurons”. The neural network consists of one or more nodes.

The data structure may include data input to the neural network. The data structure including the data input to the neural network may be stored in the computer readable medium. The data input to the neural network may include training data input in the training process of the neural network and/or input data input to the training completed neural network. The data input to the neural network may include data that has undergone pre-processing and/or data to be pre-processed. The pre-processing may include a data processing process for inputting data to the neural network. Accordingly, the data structure may include data to be pre-processed and data generated by the pre-processing. The foregoing data structure is merely an example, and the present disclosure is not limited thereto.

The data structure may include a weight of the neural network. (in the present specification, weights and parameters may be used with the same meaning.) Further, the data structure including the weight of the neural network may be stored in the computer readable medium. The neural network may include a plurality of weights. The weight is variable, and in order for the neural network to perform a desired function, the weight may be varied by a user or an algorithm. For example, when one or more input nodes are connected to one output node by links, respectively, the output node may determine a data value output from the output node based on values input to the input nodes connected to the output node and the weight set in the link corresponding to each of the input nodes. The foregoing data structure is merely an example, and the present disclosure is not limited thereto.

For a non-limited example, the weight may include a weight varied in the neural network training process and/or the weight when the training of the neural network is completed. The weight varied in the neural network training process may include a weight at a time at which a training cycle starts and/or a weight varied during a training cycle. The weight when the training of the neural network is completed may include a weight of the neural network completing the training cycle. Accordingly, the data structure including the weight of the neural network may include the data structure including the weight varied in the neural network training process and/or the weight when the training of the neural network is completed. Accordingly, it is assumed that the weight and/or a combination of the respective weights are included in the data structure including the weight of the neural network. The foregoing data structure is merely an example, and the present disclosure is not limited thereto.

The data structure including the weight of the neural network may be stored in the computer readable storage medium (for example, a memory and a hard disk) after undergoing a serialization process. The serialization may be the process of storing the data structure in the same or different computing devices and converting the data structure into a form that may be reconstructed and used later. The computing device may serialize the data structure and transceive the data through a network. The serialized data structure including the weight of the neural network may be reconstructed in the same or different computing devices through deserialization. The data structure including the weight of the neural network is not limited to the serialization. Further, the data structure including the weight of the neural network may include a data structure (for example, in the non-linear data structure, B-Tree, Trie, m-way search tree, AVL tree, and Red-Black Tree) for improving efficiency of the calculation while minimally using the resources of the computing device. The foregoing matter is merely an example, and the present disclosure is not limited thereto.

The data structure may include a hyper-parameter of the neural network. The data structure including the hyper-parameter of the neural network may be stored in the computer readable medium. The hyper-parameter may be a variable varied by a user. The hyper-parameter may include, for example, a learning rate, a cost function, the number of times of repetition of the training cycle, weight initialization (for example, setting of a range of a weight value to be weight-initialized), and the number of hidden units (for example, the number of hidden layers and the number of nodes of the hidden layer). The foregoing data structure is merely an example, and the present disclosure is not limited thereto.

Those skilled in the art may appreciate that information and signals may be expressed by using predetermined various different technologies and techniques. For example, data, indications, commands, information, signals, bits, symbols, and chips referable in the foregoing description may be expressed with voltages, currents, electromagnetic waves, magnetic fields or particles, optical fields or particles, or a predetermined combination thereof.

Those skilled in the art will appreciate that the various illustrative logical blocks, modules, processors, means, circuits, and algorithm operations described in relationship to the exemplary embodiments disclosed herein may be implemented by electronic hardware (for convenience, called “software” herein), various forms of program or design code, or a combination thereof. In order to clearly describe compatibility of the hardware and the software, various illustrative components, blocks, modules, circuits, and operations are generally illustrated above in relation to the functions of the hardware and the software. Whether the function is implemented as hardware or software depends on design limits given to a specific application or an entire system. Those skilled in the art may perform the function described by various schemes for each specific application, but it shall not be construed that the determinations of the performance depart from the scope of the present disclosure.

Various exemplary embodiments presented herein may be implemented by a method, a device, or a manufactured article using a standard programming and/or engineering technology. A term “manufactured article” includes a computer program, a carrier, or a medium accessible from a predetermined computer-readable storage device. For example, the computer-readable storage medium includes a magnetic storage device (for example, a hard disk, a floppy disk, and a magnetic strip), an optical disk (for example, a CD and a DVD), a smart card, and a flash memory device (for example, an EEPROM, a card, a stick, and a key drive), but is not limited thereto. Further, various storage media presented herein include one or more devices and/or other machine-readable media for storing information.

It shall be understood that a specific order or a hierarchical structure of the operations included in the presented processes is an example of illustrative accesses. It shall be understood that a specific order or a hierarchical structure of the operations included in the processes may be rearranged within the scope of the present disclosure based on design priorities. The accompanying method claims provide various operations of elements in a sample order, but it does not mean that the claims are limited to the presented specific order or hierarchical structure.

The description of the presented exemplary embodiments is provided so as for those skilled in the art to use or carry out the present disclosure. Various modifications of the exemplary embodiments may be apparent to those skilled in the art, and general principles defined herein may be applied to other exemplary embodiments without departing from the scope of the present disclosure. Accordingly, the present disclosure is not limited to the exemplary embodiments suggested herein, and shall be interpreted within the broadest meaning range consistent to the principles and new characteristics presented herein.

What is claimed is:

1. A method of predicting the amount of precipitation based on deep learning performed by a computing device including at least one processor, the method comprising:
receiving meteorological data measured in a weather observation system; and
predicting the amount of precipitation of a region of interest based on the meteorological data by using a deep learning model,
wherein the deep learning model is pre-trained based on a combination of a first loss function for an error calculation between a prediction value and Ground Truth (GT), and a second loss function for an error calculation different from the first loss function, and
the combination of the first loss function and the second loss function is expressed by a sum of the first loss function and the second loss function to which a predetermined weight for adjusting a relative weight between the first loss function and the second loss function is applied.

2. The method of claim 1, wherein the meteorological data includes:
a first input characteristic including an atmospheric state variable based on meteorological information measured in the weather observation system; and
a second input characteristic including a geophysical variable based on the meteorological information measured in the weather observation system.

3. The method of claim 2, wherein the atmospheric state variable includes at least one of temperature, wind direction, wind speed, the amount of precipitation, earth surface pressure, sea level pressure, and humidity at a point where the meteorological information is measured.

4. The method of claim 2, wherein the geophysical variable includes at least one of a longitude, a latitude, an altitude of the point at which the meteorological information is measured, and identification information of the weather observation system.

5. The method of claim 1, wherein the first loss function includes a loss function for calculating a Mean Squared Error (MSE), and
the second loss function includes a loss function for calculating a Mean Absolute Error (MAE).

6. The method of claim 1, wherein the deep learning model includes at least one neural network which receives the meteorological data and outputs a rainfall rate of the region of interest at a time point at which a predetermined lead time has elapsed based on an observation time point of the meteorological data.

7. The method of claim 6, wherein when the neural networks are two or more, each of the two or more neural networks receives meteorological data observed at a different time point and outputs a rainfall rate of the region of interest.

8. A computer program stored in a non-transitory computer readable storage medium, wherein when the computer program is executed by one or more processors, the computer program performs following operations for predicting the amount of precipitation based on deep learning, the operations comprising:
receiving meteorological data measured by a weather observation system; and
predicting the amount of precipitation of a region of interest based on the meteorological data by using a deep learning model, and
the deep learning model is pre-trained based on a combination of a first loss function for an error calculation between a prediction value and Ground Truth (GT), and a second loss function for an error calculation different from the first loss function, and
the combination of the first loss function and the second loss function is expressed by a sum of the first loss function and the second loss function to which a predetermined weight for adjusting a relative weight between the first loss function and the second loss function is applied

9. A computing device for predicting the amount of precipitation based on deep learning, the computing device comprising:
a processor including at least one core;
a memory including program codes executable in the processor; and
a network unit configured to receive meteorological data measured in a weather observation system,
wherein the processor predicts the amount of precipitation of a region of interest based on the meteorological data by using a deep learning model,
the deep learning model is pre-trained based on a combination of a first loss function for an error calculation between a prediction value and Ground Truth (GT), and a second loss function for an error calculation different from the first loss function, and
the combination of the first loss function and the second loss function is expressed by a sum of the first loss function and the second loss function to which a predetermined weight for adjusting a relative weight between the first loss function and the second loss function is applied.
